(19) United States
(12) Patent Application Publication
(10) Pub. No.: US 2014/0130847 A1
(43) Pub. Date: May 15, 2014

(54) PV Array Mounting for Trapezoidal Metal and Low-Slope Roofs

(71) Applicants: John Raymond West, San Rafael, CA (US); Brian Atchley, San Rafael, CA (US); Tyrus Hawkes Hudson, San Rafael, CA (US); Jose David Molina Carrasco, San Rafael, CA (US)

(72) Inventors: John Raymond West, San Rafael, CA (US); Brian Atchley, San Rafael, CA (US); Tyrus Hawkes Hudson, San Rafael, CA (US); Jose David Molina Carrasco, San Rafael, CA (US)

(73) Assignee: Zep Solar, Inc., San Rafael, CA (US)

(21) Appl. No.: 14/022,177

(22) Filed: Sep. 9, 2013

Related U.S. Application Data
(63) Continuation-in-part of application No. 13/402,846, filed on Feb. 22, 2012.
(60) Provisional application No. 61/698,292, filed on Sep. 7, 2012.

(51) Int. Cl. H01L 31/042; F24J 2/52; B23P 19/04

(52) U.S. Cl. CPC H01L 31/0422; B23P 19/04; F24J 2/5245
USPC 136/251; 29/428; 248/237

(57) ABSTRACT

Components mount an array of solar panels to trapezoidal metal roofs or flat or low-slope roofs. Couplings may secure a trapezoidal metal roof mounting adapter to the peak of the trapezoidal portion of a trapezoidal metal roof, and couplings may secure additional mounting hardware to the adapter. Solar panels may connect to the rear portion of one support and the front portion of another support to achieve an angled installation to improve sun exposure. Wind diffusers may connect to solar panels to form a barrier extending from the upper-most edge of the installed solar panel downward toward the roof to impede wind. The flat and low-slope roof solution may comprise a penetration-free mechanism to install solar panels at an angle on a flat or substantially flat surface while impeding effect from wind and maintaining an electrically grounded connection between all components.

### CROSS REFERENCES

The present application is a continuation-in-part of U.S. application Ser. No. 13/402,846, filed Feb. 22, 2012, and claims the benefit of the filing date of U.S. Provisional Patent Application Ser. No. 61/698,292 filed Sep. 7, 2012. The foregoing applications are incorporated by reference in their entirety as if fully set forth herein.

### BACKGROUND

Ever-increasing demands for energy and the ever-growing acknowledgement of the environmental damage caused by conventional fossil fuels have created an unprecedented demand for electricity generated by arrays of photovoltaic modules, or solar panels. A solar panel array necessitates infrastructure to secure the array to its site, orient the array, facilitate management and maintenance of the array, and establish a reliable electrical ground between the components of the array. Prior infrastructure technology exhibits significant shortcomings.

Commonly, photovoltaic modules are arranged on the sloped roof of a structure by securing a series of beams, or “rails” to the surface of the roof and clipping, clamping, screwing, or otherwise coupling the solar panels to the rails. This approach introduces cost and safety shortcomings. First, the rails are secured to the roof by puncturing the roof with a coupling, such as a screw or bolt. Such a perforation creates a risk of water entry at the points where the solar panel array is secured to the roof. Second, the rails themselves create a significant expense of time and material. The rails add to cost of material, manufacture, and shipping above and beyond the cost of the solar panels. The rails also increase the time installation crews must spend installing the solar array, creating additional man hours that further increase the cost of the system. Third, the rail-based system lacks a sophisticated method to provide an electrically grounded connection between the rails, solar panels, and other components to avoid creating an electrocution hazard. Lastly, the common installation method neglects other forms of roofs or other structures on which a solar panel array may be mounted. These shortcomings create an undeniable need for a solution that is more flexible, less labor intensive, and less material intensive.

### SUMMARY

The following embodiments and aspects thereof are described and illustrated in conjunction with systems, apparatus, tools, and methods which are meant to be exemplary and illustrative, not limiting in scope. In various embodiments, one or more of the above-described problems have been reduced or eliminated, while other embodiments are directed to other advantages or improvements.

An embodiment is a trapezoidal metal roof adapter featuring a substantially rigid structure with one or more apertures and one or more raised portions as well as a substantially water-impermeable lower membrane where the adapter may structurally support an additional photovoltaic array-mounting component. One or more of the apertures of the adapter is sized and located to receive a screw. One or more aperture of the adapter is sized and located to receive a bolt, machine screw, or similar coupling. The substantially rigid structure of the adapter serves as a mounting portion for a mounting foot of a photovoltaic array.

An embodiment is the installation of the aforementioned adapter by placing the bottom membrane of the adapter onto the peak of a trapezoid of a trapezoidal metal roof and applying a screw through an aperture of the adapter into the roof, then applying a machine screw through an aperture of a mounting component and into an aperture of the adapter so that the adapter structurally supports the mounting component.

An embodiment is a photovoltaic array consisting of (i) a frame member enclosing a photovoltaic laminate where at least one side wall of the frame member has at least one female receiving portion integrated into its outside surface, (ii) a first support structure with an upper and lower portion, (iii) a second support structure with an upper and lower portion, (iv) a coupling comprising a catch, an arm, a tooth, and a flange, and (v) a wind diffuser with an aperture, where the coupling connects the frame member to the supports and the wind diffuser such that all are electrically grounded and the supports structurally support the frame member and photovoltaic laminate. In the array, the coupling connects the groove of the frame member to an aperture of the supports. In the array, the frame member connects to the lower portion of the first support and the upper portion of the second support. In the array, the coupling connects the groove of the frame member to the wind diffuser.

An embodiment is a photovoltaic array consisting of (i) a frame member enclosing a photovoltaic laminate where at least one side wall of the frame member has at least one female receiving portion integrated into its outside surface, (ii) a second frame member enclosing a photovoltaic laminate where at least one side wall of the frame member has at least one female receiving portion integrated into its outside surface, (iii) a first foot with a first leg, (iv) a second foot with a second, longer leg, (v) a coupling with a male portion (vi) a wind diffuser (vii) a ballast block, and (viii) a support structure where the first foot rests on a surface, such as a roof, the second foot rests upon a surface, such as a roof, the first and second legs extend upward from the first and second feet respectively, the first and second legs are topped by couplings, the male portions of the couplings engage the female receiving portion of the frame members so that the photovoltaic module extends downward at an angle with respect to the surface, a ballast block rests atop both the first and second foot, a support structure extends from the uppermost end of the first photovoltaic module to the second photovoltaic module, and a wind diffuser extends downward from the upper-most edge of the first photovoltaic module so that the PV modules are supported on a flat or low-slope surface at an angle. An interlock may connect the array to an adjacent array.

In addition to the exemplary aspects and embodiments described above, further aspects and embodiments will become apparent by reference to the figures and by study of the following detailed descriptions.

### BRIEF DESCRIPTION OF THE DRAWINGS

Demonstrative embodiments are illustrated in referenced figures and drawings. It is intended that the embodiments and figures disclosed herein are to be considered illustrative rather than restrictive.

FIG. 1 is an exploded view of a trapezoidal metal roof adapter and a leveling foot.

FIG. 2 is a trapezoidal metal roof adapter and a leveling foot installed on a trapezoidal metal roof.

FIG. 3 is a photovoltaic array for a flat or low-slope roof.

FIG. 4 is a detailed view of a support from FIG. 3 connected to photovoltaic modules by couplings.

FIG. 5 is a detailed view of a wind diffuser from FIG. 3 connected to photovoltaic modules by couplings.

FIGS. 6A and 6B are views of a trapezoidal metal roof adapter.

FIGS. 7A and 7B are views of a support.

FIG. 8 is a view of a coupling.

FIGS. 9A and 9B are views of a photovoltaic array.

### DETAILED DESCRIPTION OF ONE OR MORE EMBODIMENTS THE INVENTION

Terms. With reference to the figures and description herein but without limitation:

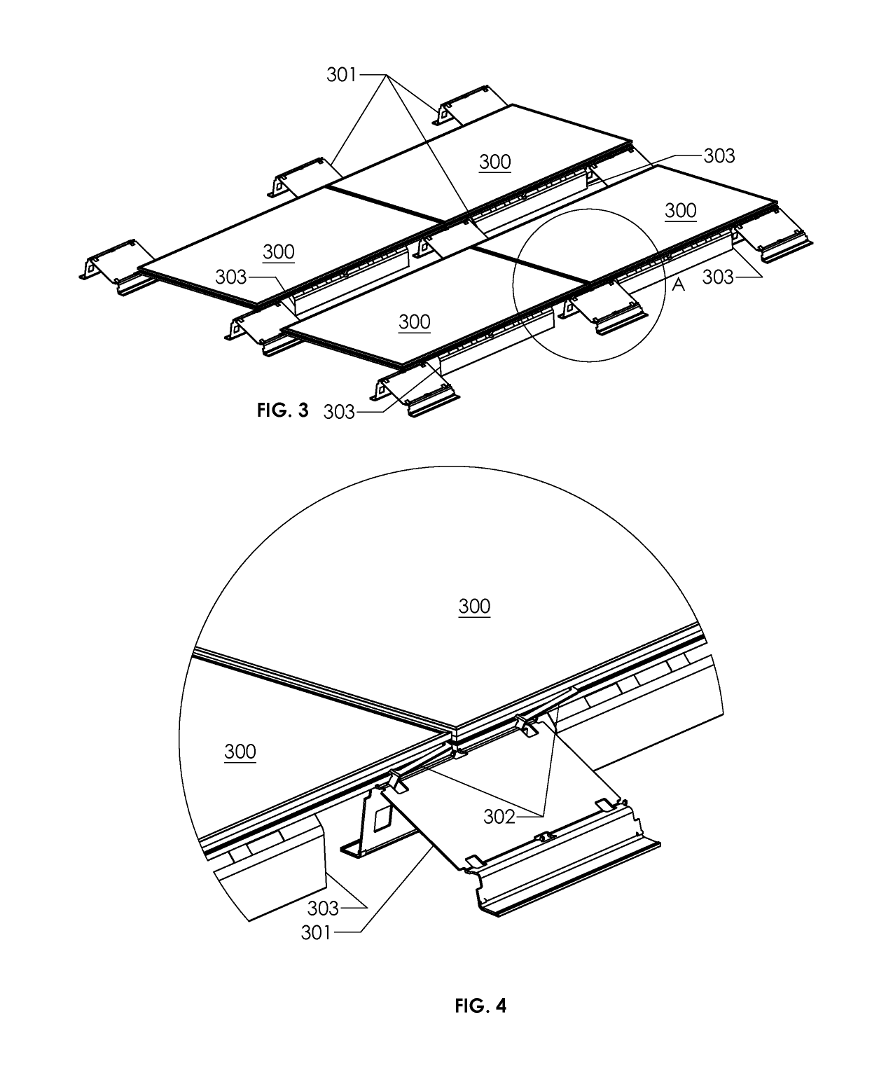

Adjacent refers to being positioned next to or adjoining or neighboring, or having a common vertex or common side. Thus, adjacent PV panels would include PV panels that have one side close to (from a few inches apart to abutting) and facing one side of another PV panel. Sometimes, but not always, the corners of adjacent panels align; so four adjacent panels would have one corner each that nearly or actually touch the other three corners, such as exemplified at FIGS. 3 and 4 and their descriptions.

Adjustable refers to the capability of being changed so as to match or fit.

Adjustably connected refers to an object, item, mechanism, apparatus, combination, feature, link or the like that loosely, slidable, or rigidly links, interlocks, joins, unites or fastens two or more things together in a manner that can be changed so as to match or fit.

Attach or attachment refers to one or more items, mechanisms, objects, things, structures or the like which are joined, fastened, secured, affixed or connected to another item, or the like in a permanent, removable, secured or non-permanent manner. As an example, a PV module may be attached to a support as exemplified at FIG. 4 and its descriptions.

Axis of rotation refers to a center around which something rotates, sometimes considered a straight line through all fixed points of a rotating rigid body around which all other points of the body move in a circular manner.

Beneath refers to extending or being situated directly or substantially underneath, typically with close proximity or contact.

Between refers to being situated, located, or otherwise oriented at, in, or across the space separating two objects or regions. For example, wind diffuser 303 is between supports 301 in FIG. 3.

Connect or connecting refers to loosely, slidably, or rigidly bringing together or into contact with or joining or fastening to form a link or association between two or more items, mechanisms, objects, things, structures or the like.

Connector refers to an object, item, mechanism, apparatus, combination, feature, link or the like that loosely, slidable, or rigidly links, interlocks, joins, unites or fastens two or more things together. May also include a device, an object, item, mechanism, apparatus, combination, feature, link or the like for keeping two parts of an electric or electronic circuit in contact.

Coplanar refers to the circumstance where two or more objects are situated, located, or otherwise substantially oriented in the same plane.

Couple refers to loosely, slidably, or rigidly joining, linking, interlocking, connecting or mating two or more objects or items, mechanisms, objects, things, structures or the like together.

Coupling refers to an object, item, mechanism, apparatus, combination, feature, link or the like that loosely, slidably, or rigidly joins, links, mates, interlocks, or connects two things together.

Double male connector refers to a connector (see above) having two male or insertable members, usually used for connecting two female or receiving parts or coupling members together.

Disengage refers to detaching, freeing, loosening, extricating, separating or releasing from something that holds-fast, connects, couples or entangles. See Engagement below.

Enable refers to facilitating or making possible, able, feasible, practical, operational, or easy; or to cause to operate.

End refers to a final part, termination, extent or extremity of an object, item, mechanism, apparatus, combination, feature, or the like that has a length.

Engage refers to interlocking or meshing or more items, mechanisms, objects, things, structures or the like. See Disengage above.

Frame refers to an essentially rigid structure that surrounds or encloses a periphery of an item, object, mechanism, apparatus, combination, feature, or the like.

Freely refers to being without or exempt from substantial restriction or interference by a given condition or circumstance. May also refer to being unobstructed, unconstrained, unrestricted or not being subject to external restraint.

Gap refers to a break, void, opening, cleft, breach, aperture, separation, or space, as well as an interruption of continuity, between two objects, or within an object.

Groove refers to a long, narrow cut, rut, indentation, channel, furrow, gutter, slot or depression often used to guide motion or receive a corresponding ridge or tongue.

Height adjustable refers to change or adapt to bring items, objects, mechanisms, apparatus, combinations, features, components or the like into a proper, desired or preferred relationship of a distance or elevation above a recognized level, such as the ground or a support surface.

Insertable refers to an object, item, mechanism, apparatus, combination, feature, link or the like which is capable of being put in, entered into, set within, introduced, inset, inserted, placed, fit or thrust into another an object, item, mechanism, apparatus, combination, feature, link or the like.

Integral with refers to being essential or necessary for completeness, constituent, completing, containing, entire, or forming a unit. May also refer to consisting or composed of parts that together constitute a whole.

Laminate or PV laminate refers to a photovoltaic device having an interconnected assembly of solar cells, also known as photovoltaic cells which is frequently, but not always, laminated with glass and/or other materials.

Length refers to a measurement or extent of an object, item, mechanism, apparatus, combination, feature, link or the like from end to end, usually along the greater or longer of the two or three dimensions of the body; in distinction from breadth or width.

Located refers to where an object or a series of objects is physically situated with respect to one or more other objects.

Locked refers to fastened, secured or interlocked.

Orthogonally refers to relating to or composed of right angles, perpendicular or having perpendicular slopes or tangents at a point of intersection.

Near refers to a short distance from an object or location.

Perimeter refers to an essentially continuous line forming the boundary, periphery or circuit of a closed geometric figure; the outer limits of an area.

Photovoltaic module (sometimes referred to as a PV module, solar panel, solar module, or photovoltaic panel) refers to a packaged, interconnected assembly of solar cells, also known as photovoltaic cells, frequently, but not always, laminated with glass and other materials and sometimes surrounded by a frame. A plurality of PV modules are commonly used to form a larger photovoltaic system referred to as a PV array (see below), to provide electricity for commercial, industrial and residential applications.

Pivotally refers to or relates to an object, item, mechanism, apparatus, combination, feature, link or the like serving as a pivot or the central point, pin, shaft or contact on which another object, item, mechanism, apparatus, combination, feature, link or the like turns, swings, rotates or oscillates.

Positionable refers to an object, item, mechanism, apparatus, combination, feature, link or the like which is capable of being positioned, placed or arranged in a particular place or way.

Preload refers to the force that must be overcome to separate a joint once force is applied to attach a coupling to the joint. The applied force deforms the coupling and/or one or more of the components of the joint and becomes the force that must be overcome to separate the joint.

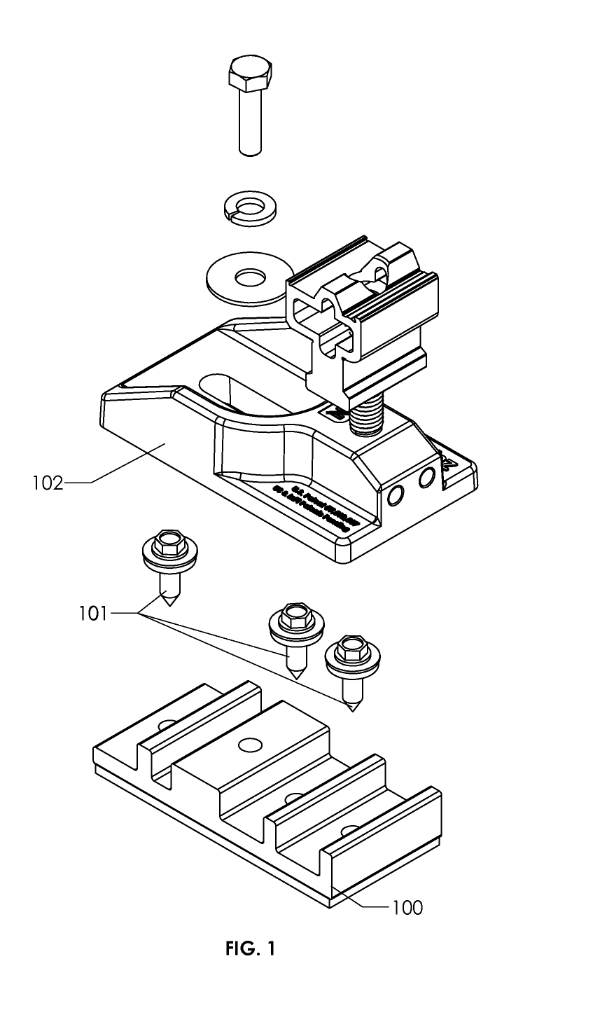

Puck refers, without limitation, to a block or block-like adapter. A puck is exemplified at 100 in FIG. 1.

PV laminate refers to a photovoltaic device having an interconnected assembly of solar cells, also known as photovoltaic cells which is frequently, but not always, laminated with glass and/or other materials. A PV laminate with an integral frame which may support the PV laminate is sometimes referred to as a PV module.

PV module refers to a photovoltaic module (sometimes referred to as a solar panel or photovoltaic panel) is a packaged interconnected assembly of solar cells, also known as photovoltaic cells, frequently, but not always, laminated with glass and other materials and sometimes surrounded by a frame. A plurality of PV modules are commonly used to form a larger photovoltaic system referred to as a PV array (see below), to provide electricity for commercial, industrial and residential applications.

PV array refers to a plurality of photovoltaic modules connected together often in a pattern of rows and columns with module sides placed close to or touching other modules.

Rail refers to refers to a relatively straight, usually essentially evenly shaped along its length, rod, beam, girder, profile or structural member or the like, or plurality of such, of essentially rigid material used as a fastener, support, barrier, or structural or mechanical member.

Rail member refers to a structural entity, element or unit (or part of such entity, element, or unit) that acts as or embodies a rail.

Removable refers to one or more items, mechanisms, objects, things, structures or the like which are capable of being removed, detached, dismounted from or taken-away from another item or the like, or combination.

Rectilinear refers to one or more items, mechanisms, objects, things, structures or the like which are essentially bounded by, characterized by or forming straight and substantially parallel lines.

Rigidly couples refers to joining, linking, connecting or mating two or more objects or items, mechanisms, objects, things, components, structures or the like together in a non-flexible manner that is difficult to bend or be forced out of shape.

Roof refers to a structure or protective covering that covers or forms the upper covering or top of a building. The upper surface of a roof is often used as a support surface for mounting, connecting or otherwise attaching a PV module or a PV array.

Rotatably refers to one or more items, mechanisms, objects, things, structures or the like which are capable of being rotated, revolved or turned around or about an axis or center.

Skirt refers to an edging, molding or covering that may be fixed to the edge of a PV module to conceal or block the bottom area under a PV array when the PV array is mounted to a support surface.

Span refers to an extent or measure of space between, or the distance between two points or extremities.

Support or supporting refers to one or more items, mechanisms, objects, things, structures or the like which are capable of bearing weight or other force, often to keep the item or the like from falling, sinking, slipping or otherwise moving out of a position.

Support structure refers to a structure, such as a roof, table or the ground which may provide a base for securing PV modules to form a PV array.

Threaded refers to one or more items, mechanisms, objects, things, structures or the like which have, embody or include an essentially helical or spiral ridge or rib, as on a screw, nut, or bolt.

Various locations refers to places, positions or sites that are different from one another, more than one, individual or separate.

Vertical height adjustment refers to change or adapt to bring items, mechanisms, objects, things, components, structures or the like or components into a proper, desired or preferred relationship of a distance or elevation above a recognized level, such as the ground or a support surface.

Width refers to the state, quality, or fact of being wide or a measurement or extent of something from side to side; in distinction from breadth or length.

FIG. 1 is an isometric exploded view of a puck, block, adapter, or the like, such as trapezoidal mounting adapter 100, with fasteners, such as screws 101, for attaching to a roof panel, and leveling foot 102, as previously described in prior filed patents and patent applications by the instant inventor, for the purpose of attaching an array of PV modules. Part 100 is an embodiment of a trapezoidal metal roof adapter featuring a substantially rigid structure with one or more apertures and one or more raised portions as well as a substantially water-impermeable lower membrane where the adapter may structurally support an additional photovoltaic array-mounting component. One or more of the apertures of the adapter 200 is sized and located to receive a screw. One or more aperture of the adapter 100 is sized and located to receive a bolt, machine screw, or similar coupling. The substantially rigid structure of the adapter 100 serves as a mounting portion for a mounting foot of a photovoltaic array.

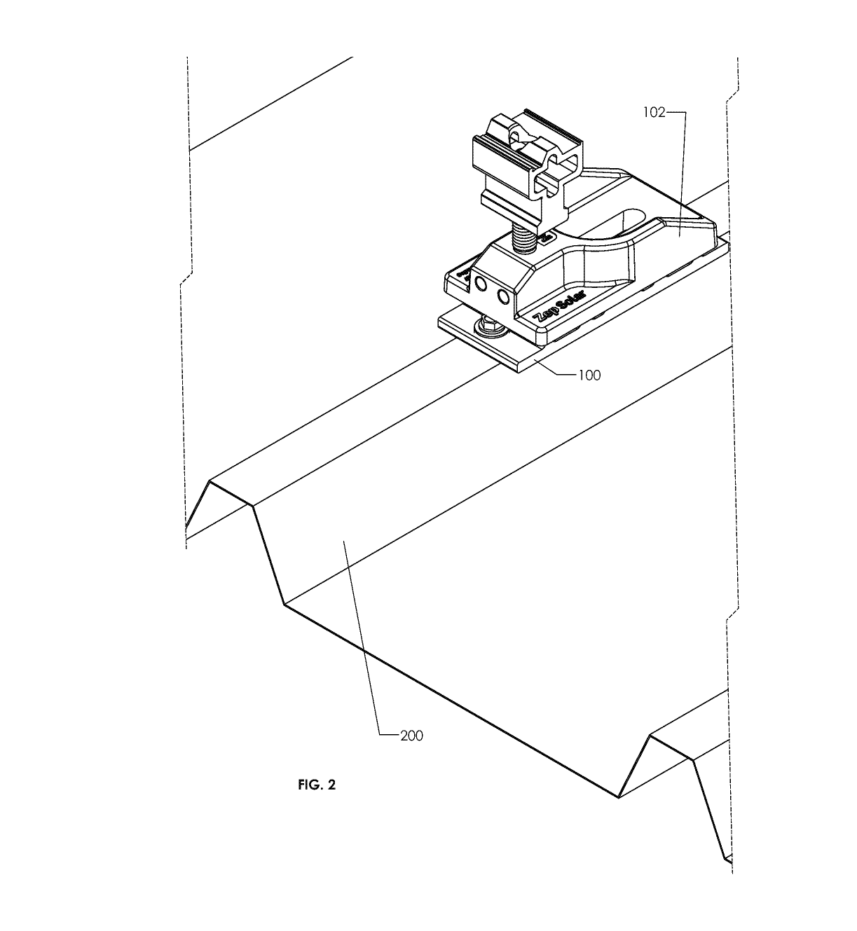

FIG. 2 is an oblique view of the assembled components of FIG. 1, shown mounted to a roof panel or other support structure, such as trapezoidal roof panel 200. Operationally, installation occurs by placing the bottom membrane of the adapter (100) onto the peak of a trapezoid of a trapezoidal metal roof (200) and applying a screw through an aperture of the adapter into the roof, then applying a machine screw through an aperture of a mounting component (102) and into an aperture of the adapter (100) so that the adapter (100) structurally supports the mounting component (102).

FIG. 3 is an oblique view of an array of PV modules 300 mounted to support structures, such as corner supports 301. Corner supports 301 hold PV modules 300 at an angle relative to the surface on which the corner supports are resting, for example, such that the PV module surface is favorably inclined toward the sun, or the path of the sun. Corner supports 301 are shown as (optionally) mechanically attached and electrically ground-bonded to PV modules 300 as by a clip, bracket, fastener, or the like, such as a lever clip 302, as shown in FIG. 4, and previously described in prior filed patents and patent applications by the instant inventors. Further shown on each PV module 300 (but may be on one or more, but not all) is a panel, wall, deflector, or the like, such as wind diffuser 303, which is also shown as (optionally) attached to PV module 300 as by lever clip 302. FIGS. 3 and 4 are embodiments of a photovoltaic array consisting of (i) a frame member enclosing a photovoltaic laminate 300 where at least one side wall of the frame member has at least one female receiving portion integrated into its outside surface, (ii) a first support structure 301 with an upper and lower portion, (iii) a second support structure 301 with an upper and lower portion, (iv) a coupling 302 comprising a catch, an arm, a tooth, and a flange, and (v) a wind diffuser 303 with an aperture, where the coupling 302 connects the frame member to the supports 301 and the wind diffuser 303 such that all are electrically grounded and the supports structurally support the frame member and photovoltaic laminate. In the array, the coupling 302 connects the groove of the frame member to an aperture of the supports 301. In the array, the frame member connects to the lower portion of the first support 301 and the upper portion of the second support 301. In the array, the coupling connects the groove of the frame member to the wind diffuser 303.

FIG. 4 is a close-up oblique view of corner support 301 attached to PV module 300 as by lever clip 302.

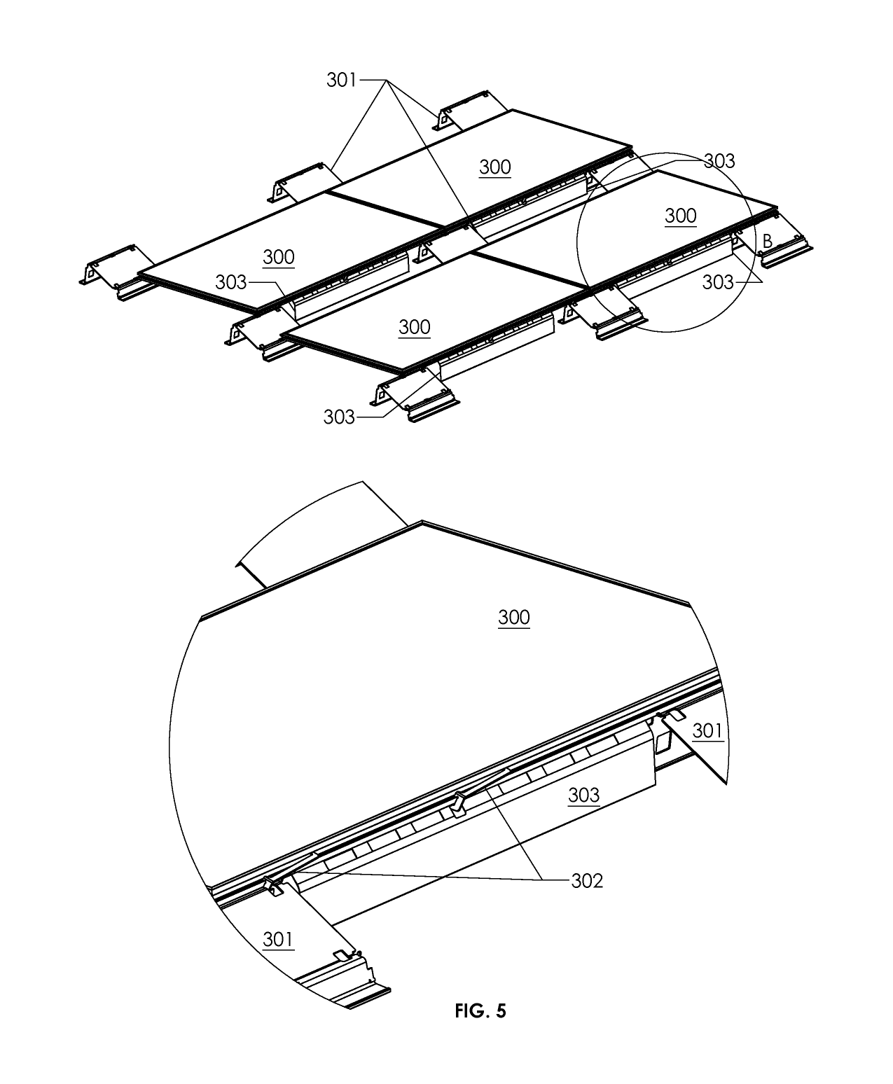

FIG. 5 is a close-up oblique view of wind diffuser 303 attached to PV module 300 as by lever clip 302.

The trapezoidal metal roof puck and flat- or low-sloped roof solution provide elegantly simple means to efficiently, quickly, and inexpensively install solar panel arrays on commonly-used forms of roofing or applicable surfaces. As discussed in greater detail below, the puck provides an interface between a trapezoidal roof and a rail-free mounting system that maintains a grounded connection and reduces material and labor costs, and the flat-roof solution provides a simple, effective, and safe structure and method for installing solar panel arrays on flat or substantially flat roofs.

As shown and described in FIGS. 1-2, puck adapter 100 for trapezoidal metal roofs may be secured to a surface, such as the peak of a trapezoid of a trapezoidal metal roof, using couplings such as screws 101. A leveling foot 102 may be secured to puck adapter 100 using a bolt or other coupling, as shown in FIG. 1. Puck 100, screws 101, and leveling foot 102 may be aluminum or another alloy, metal, or conductive material, and the contact between them maintains an electrically grounded connection. Once leveling foot 102 connects to puck 100, a rail-free solar panel array may be mounted to the trapezoidal metal roof as discussed in greater detail in a separate application by the instant inventor.

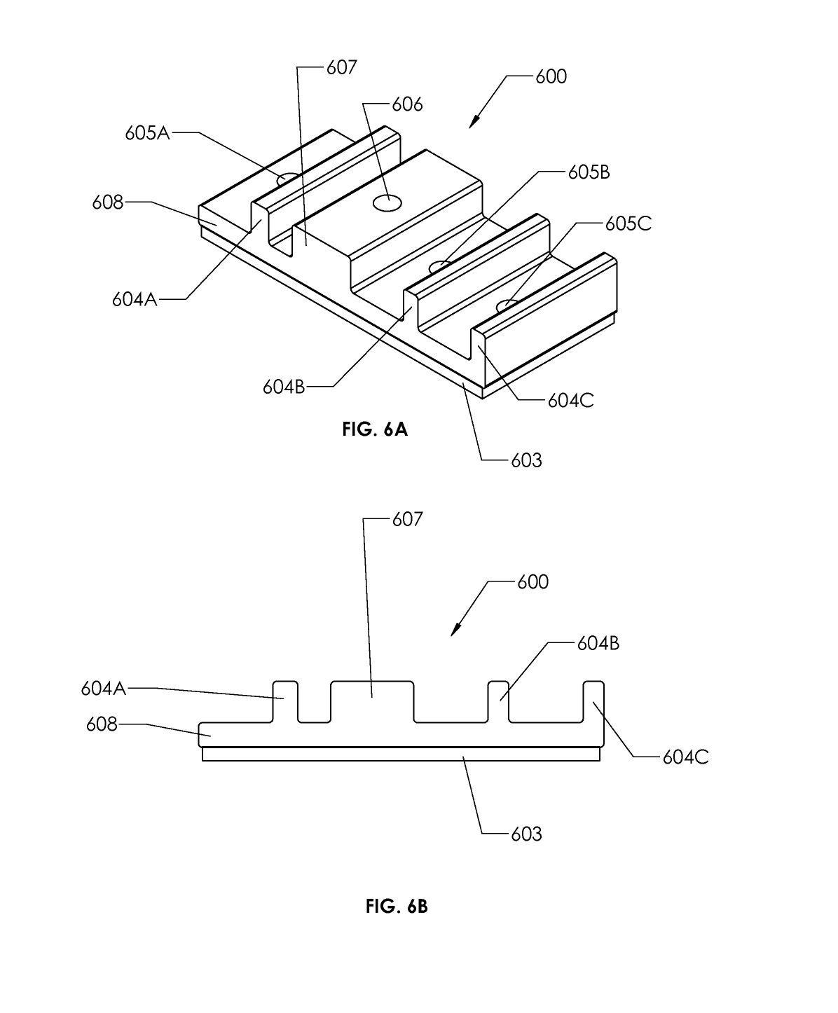

Referring now to FIGS. 6A and 6B, a puck is shown. A puck such as puck 600 may include a membrane 603, a base 608 with one or more coupling apertures 605A-605C, one or more supports such as supports 604A-604C, a block 607 with a leveling-foot aperture 606. Connecting a leveling foot to leveling-foot aperture 606 using a bolt or other coupling may permit the leveling foot to pivot. Depending on how the leveling foot pivots, it may rest on one or more supports 604A-604C which may prevent the leveling foot from bowing and placing undue torque on the bolt securing the leveling foot to puck 600. Screws or other couplings may secure puck 600 to a roof through coupling apertures 605A-605C. So securing puck 600 to a roof or other surface may compress membrane 603, providing increased water resistance to prevent atmospheric moisture from entering the perforation in the roof or other surface created by the screw or other coupling.

Referring now to FIGS. 3-5, a solar panel array is shown assembled with components that avoid penetrating the surface on which they are mounted and form an electrically grounded connection between all components. The array consists of supports 301 that secure and orient solar panels 300, wind diffusers 303, and lever clips 302 that secure the components of the array to one another.

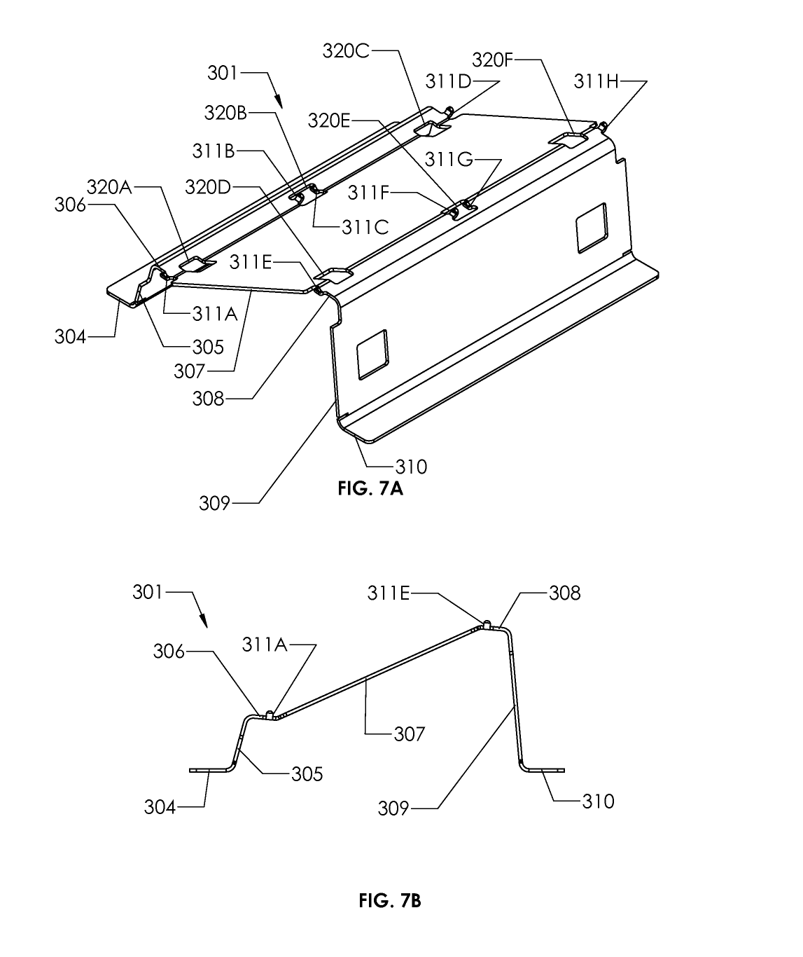

Referring now to FIGS. 7A and 7B, a support such as support 301 is shown. Support 301 may include a rear foot 304, a rear leg 305, a rear plateau 306 with lever apertures 320A-320C, a slope 307, a front plateau 308 with lever apertures 320D-320F, a front leg 309, a front foot 310, and stoppers 311A-311H. Support 301 may be formed of aluminum, another alloy or metal, or another electrically conductive material. As shown and described in FIG. 3, supports 301 may be aligned in rows such that one support 301 supports the adjacent corners of two adjacent solar panels 300. A portion of the lower surface of the frame of the solar module 300 may rest on the lower plateau 306 or upper plateau 308 and may abut stoppers 311A-311H. Solar panels 300 may then be secured to supports 301 using lever clips 302.

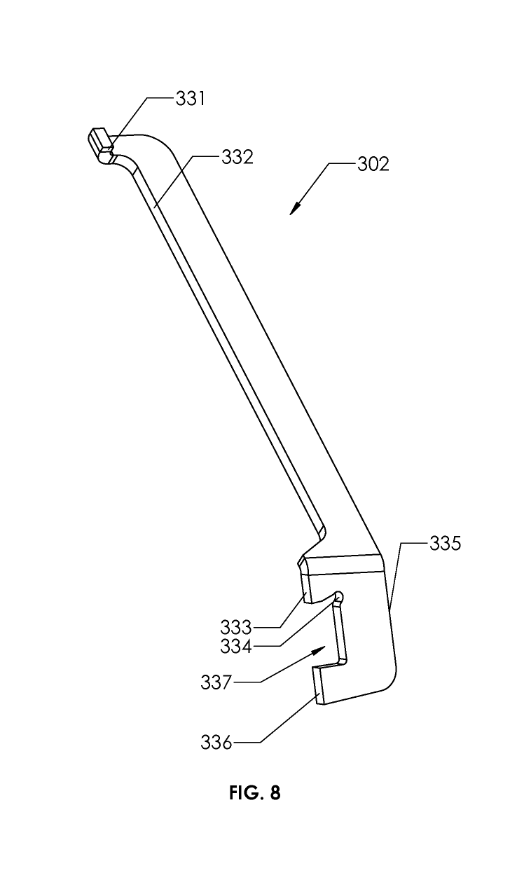

Referring now to FIG. 8, a lever clip such as lever clip 302 is shown. Lever clip 302 may include a catch 331, an arm 332, a tooth 333, a notch 334, a head 335, and a flange 336 that form a cutout 337. Flange 336 may be placed into a lever aperture 320A-320F while tooth 33 may be placed into the groove of the frame of a solar panel 300 (discussed in detail in other applications by the instant inventor). Lever 332 may then be angled downward such that catch 331 is placed in the groove of the frame of solar panel 300. Tooth 333 may “bite” through any anodized surface that may exist on the frame of solar panel 300 such that conductive surfaces contact conductive surfaces of all components, creating an electrically grounded connection between the components. Wind diffuser 303 may connect to solar panel 300 using lever clamp 302 in a similar fashion.

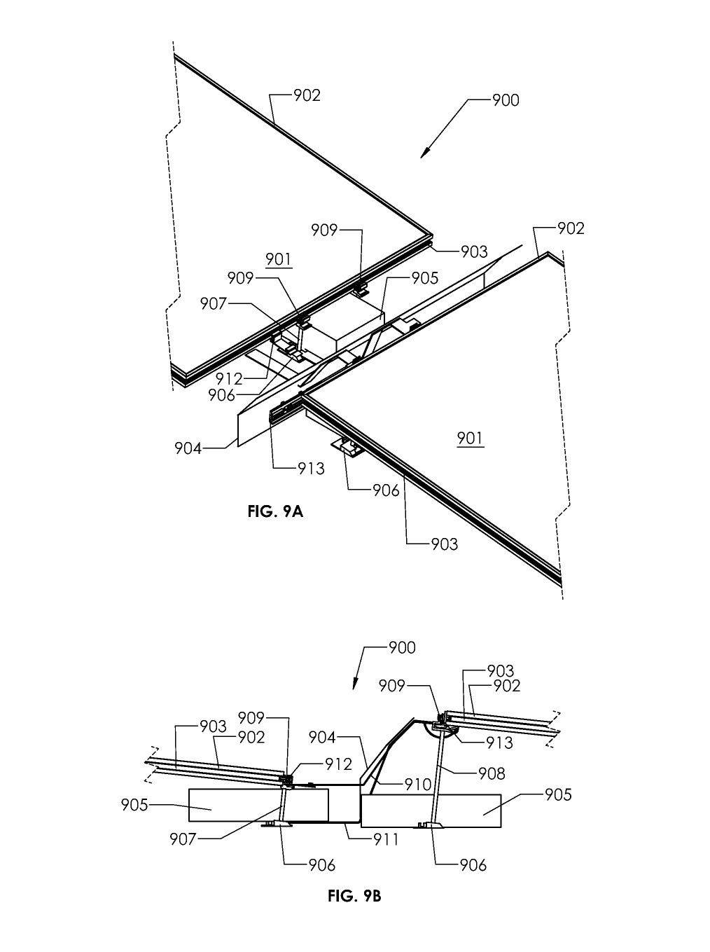

Referring now to FIGS. 9A and 9B, another embodiment of a flat-roof or low-slope roof mounting solution is shown. An array such as array 900 may include PV modules 901 with frames 902 incorporating grooves 903, a wind diffuser 904, ballast blocks 905, feet 906, front legs 907, rear legs 908, rockits 909, upper supports 910, lower supports 911, groove extensions 912, and interlocks 913. Feet 906 may be placed on a surface, including without limitation a flat or low-slope roof Front legs 907 may extend upward from a first foot and terminate in rockits 909. Rear legs 908 may extend from a second foot and terminate in rockets 909. Rockits 909 may be inserted into the grooves 903 of the PV modules 901 such that the PV module 901 extends downward from the rockits 909 atop the rear legs 908 to the rockits 909 atop the front legs 907, orienting the PV module 901 at an angle. Ballast blocks 905 may rest atop feet 906 to secure feet 906 to the relevant surface. An interlock 913 may connect to the groove of one PV module 901 and to the groove of an adjacent PV module 901. Lower support 911 may engage a rockit 909 of a rear leg 908 and angle downward to the foot 906 of the next PV module in a row. Upper support 910 may engage a rockit 909 of a rear leg 908 and angle downward to engage a groove extension 912 that engages rockit connected to the groove of the next PV module 901 in the series. Wind diffuser 904 may rest on or above upper support 910 and lower support 911 and extend downward behind ballast block 905. Array 900 may secure an array of PV modules 901 to a surface. Ballast blocks 905 may weigh down feet 906 which may connect to the remainder of the array, and wind diffuser 904 may prevent or reduce the force of wind beneath the array 900 and specifically beneath the PV module 901 that may cause lift or otherwise create unwanted movement of the array 900. The remaining components of the array 900 provide structural support for the PV modules 901. Array 900 is an embodiment of a photovoltaic array consisting of (i) a frame member enclosing a photovoltaic laminate (901) where at least one side wall of the frame member (902) has at least one female receiving portion (903) integrated into its outside surface, (ii) a second frame member (902) enclosing a photovoltaic laminate where at least one side wall of the frame member has at least one female receiving portion (903) integrated into its outside surface, (iii) a first foot (906) with a first leg (907), (iv) a second foot (906) with a second, longer leg (908), (v) a coupling with a male portion (909) (vi) a wind diffuser (904) (vii) a ballast block (905), and (viii) a support structure (910, 911) where the first foot (906) rests on a surface, such as a roof, the second foot (906) rests upon a surface, such as a roof, the first leg (907) and second leg (908) extend upward from the first and second feet (906) respectively, the first leg (907) and second leg (908) are topped by couplings (909), the male portions of the couplings engage the female receiving portion (903) of the frame members (902) so that the photovoltaic module extends downward at an angle with respect to the surface, a ballast block (905) rests atop both the first and second foot (906), a support structure (910) extends from the uppermost end of the first photovoltaic module to the second photovoltaic module, and a wind diffuser (904) extends downward from the upper-most edge of the first photovoltaic module so that the PV modules are supported on a flat or low-slope surface at an angle. An interlock (913) may connect the array to an adjacent array.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions, and sub-combinations as are within their true spirit and scope.

1. A trapezoidal metal roof adapter comprising:
a substantially rigid structure comprising one or more apertures and one or more raised portions; and
a substantially water-impermeable membrane; wherein an additional photovoltaic array-mounting component may engage the adapter such that said component is structurally supported by a raised portion.

2. The trapezoidal metal roof adapter of claim 1 wherein one or more aperture is sized and located to receive a screw.

3. The trapezoidal metal roof adapter of claim 1 wherein one or more aperture is sized and located to receive a bolt, machine screw, or similar coupling.

4. The trapezoidal metal roof adapter of claim 1 wherein the substantially rigid structure comprises a mounting portion for receiving a mounting foot for a photovoltaic array.

5. A method of installing a trapezoidal metal roof adapter comprising the steps of:
placing an adapter on the peak of a trapezoid of a trapezoidal metal roof such that the bottom surface of the membrane contacts the top surface of the peak and a screw or other coupling is affixed to the peak and the adapter through an aperture in the adapter; and
placing an array-mounting component onto said adapter and affixing a machine screw or other coupling to said adapter through an aperture in said array-mounting component such that the raised portions of said adapter structurally support said array-mounting component.

6. A photovoltaic array comprising:
a frame member enclosing a single photovoltaic laminate, that frame member having a plurality of side wall portions and at least one side wall portion having at least one interlocking means comprising a female receiving portion integrated into the outside surface; a first support comprising a lower portion, an upper portion, and one or more apertures;
a second support comprising a lower portion, and upper portion, and one or more apertures;
a coupling comprising a catch, an arm, a tooth, and a flange; and
a wind diffuser comprising an aperture;
wherein said couplings connects (i) said frame member to said lower portion of said first support and said upper portion of said second support such that said frame member is structurally supported by said first and second supports and oriented at an angle, and said first support and said second support are electrically grounded to said frame member, and (ii) said frame member to said wind diffuser such that said wind diffuser is electrically grounded to said frame member.

7. The photovoltaic array of claim 6 wherein said coupling connects the groove of the frame member to an aperture of the support.

8. The photovoltaic array of claim 6 wherein a first portion of a frame member connects to the lower portion of a first support and a second portion of said frame member connects to the upper portion of a second support.

9. The photovoltaic array of claim 6 wherein said coupling connects the groove of the frame member to said wind diffuser

10. The photovoltaic array of claim 6 wherein the tooth of said coupling punctures, scrapes, or otherwise penetrates the outermost surface of said frame member.

11. A photovoltaic array comprising:
a first frame member enclosing a single photovoltaic laminate, that frame member having a plurality of side wall portions and at least one side wall portion having at least one interlocking means comprising a female receiving portion integrated into the outside surface;
a second frame member enclosing a single photovoltaic laminate, that frame member having a plurality of side wall portions and at least one side wall portion having at least one interlocking means comprising a female receiving portion integrated into the outside surface;
a first foot with a first leg;
a second foot with a second leg of a greater vertical dimension than said first leg;
a coupling with a male portion;
a wind diffuser;
a ballast block; and
a support structure;
wherein said first foot rests upon a surface, said second foot rests upon a surface, said first leg extends upward from said first foot; said second leg extends upward from said second foot; said couplings connect to the topmost portion of said first and second leg; the male portions of said couplings engage the female connector of said frame member such that said photovoltaic module extends downward at an angle with respect to the surface; said ballast blocks rest atop said first and second foot; said support structure extends from the uppermost end of a first photovoltaic module to a second photovoltaic module; and said wind diffuser extends downward from the upper-most edge of the first photovoltaic module; such that the PV modules are supported on a flat or low-slope surface at an angle.

12. The photovoltaic array of claim 11 wherein an interlock connects two laterally adjacent photovoltaic modules.
